(19) United States
(12) Patent Application Publication
(10) Pub. No.: US 2007/0126119 A1
(43) Pub. Date: Jun. 7, 2007

(54) Semiconductor element, production process thereof, semiconductor laser and production process thereof

(76) Inventors: Ryu Washino, Chigasaki (JP); Takeshi Kikawa, Kodaira (JP); Yasushi Sakuma, Tokyo (JP); Kaoru Okamoto, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/454,832

(22) Filed: Jun. 19, 2006

(30) Foreign Application Priority Data
Dec. 6, 2005 (JP) 2005-351834

(51) Int. Cl. H01L 23/48; H01L 23/52; H01L 29/40

(52) U.S. Cl. 257/745; 257/744

(57) ABSTRACT

An object of the present invention is to provide a semiconductor production technology capable of preventing the peeling of the electrode which occurs in die bonding or wire bonding. There is provided a semiconductor element having an electrode in a surface or in a rear face of a semiconductor substrate, the semiconductor element having a structure in which an amorphous silicon layer 106 is inserted in between an electrode 107 and a semiconductor substrate 101, wherein hydrogen is not added to the amorphous silicon layer 106. Furthermore, an amorphous silicon layer 104 is inserted also in the interface between an electrode 105 and an insulating layer 103, and in the interface between the insulating layer and the semiconductor substrate. Moreover, the present invention is equally applicable to a semiconductor laser having an insulating layer, which serves as a reflective layer, in an oscillating surface side of light, and insulating layers, which serve as a multilayer reflective layer, in a non-oscillating surface side.

### BACKGROUND OF THE INVENTION

The present invention relates to a production technology of semiconductor elements and semiconductor lasers, and particularly relates to a technology effective when applied to a mounting process of these semiconductor products.

For example, semiconductor elements are assembled in a mounting process after being diced. This assembly includes steps of fixing (die bonding) to a mounting substrate with the use of solder, and of wire connecting (wire bonding) for the purpose of energizing, and the like. In these die bonding and wire bonding, a stud whose primary material is gold, the gold having a small contact resistance and little material degradation which occurs over time, is formed, and these die bonding and wire bonding are carried out via this stud. Moreover, in between an electrode and a semiconductor substrate, an insulating layer is formed for the purpose of reducing the capacitance of semiconductor elements, and thus the electrode has a multilayer structure consisting of several kinds of materials.

By the way, although in the above assembly, the electrode is formed on the substrate or a crystal thin film of the semiconductor element, a high adhesion thereto is essential. However, because the adhesion between gold, which is the main material of the electrode, and the semiconductor substrate is not sufficient, there is commonly employed a structure in which another material is formed as an intermediate layer between the gold and the semiconductor substrate in order to obtain a high adhesion.

Moreover, for the purpose of reducing the capacitance of semiconductor elements, the electrode has a multilayer structure consisting of several kinds of materials, and therefore, when carrying out die bonding or wire bonding in the electrode having a multilayer structure, physical stresses from the outside to the electrode, such as heat and a load, are applied, thereby causing peeling in the electrodes having an insufficient adhesion. This peeling often occurs in the interface between respective layers in the multilayer structure, and especially peeling in the bonded interface between the insulating layer and the semiconductor substrate likely occurs, and thus the improvement in the adhesion is needed.

Then, it is an objective of the present invention to provide a semiconductor production technology capable of preventing the peeling of electrodes which occurs in die bonding or wire bonding.

The above and other objectives and novel features of the present invention will be apparent from the description of this specification and the accompanying drawings.

### SUMMARY OF THE INVENTION

A summary of exemplary inventions among the inventions disclosed in this application will be described briefly as follows.

In the present invention, there is employed a structure in which an amorphous silicon layer, in which many dangling bonds exist, is inserted in the interface between an electrode and a semiconductor substrate and/or in the interface between an insulating layer formed underneath the electrode and the electrode and/or in the interface between the insulating layer and the semiconductor substrate. The surface of the amorphous silicon layer, in which many dangling bonds exist, is extremely active, so if bonded, the bonding strength to the semiconductor substrate, to the insulating layer, and to an electrode stud will improve dramatically.

The amorphous silicon layer in which these many dangling bonds exist can be obtained by adding no active gas, such as hydrogen, oxygen, and nitrogen when forming the amorphous silicon layer.

Moreover, when forming the amorphous silicon layer, an ECR sputtering method which is a low damaging type is used. This is because in order to suppress physical damages applied to the semiconductor substrate and oxidization of the surface of the semiconductor due to high temperature, a sputtering method which is a process in a vacuum having extremely few impurities is used. In particular, by using an ECR sputtering method the damages to a semiconductor laser during deposition by a sputtering method can be reduced, and additionally a precise insulating layer which is in a close to crystal condition can be obtained.

Moreover, as the thickness of the amorphous silicon layer, the film thickness is preferably 2 nm or more. This is because if the thickness is less than 2 nm, the peel strength is low and a sufficient adhesion can not be obtained. However, by setting the thickness to 2 nm or more, the amorphous silicon layer becomes uniform in the interface between the semiconductor substrate and the insulating layer or between the insulating layer and the electrode, and thus it is possible to satisfy the adhesion strength sufficiently.

The advantages obtained by the exemplary inventions among the inventions disclosed in the present application will be described briefly as follows.

According to the present invention, by inserting the amorphous silicon layer, in which many dangling bonds exist, in the interface between the electrode and the semiconductor substrate and/or in the interface between the electrode and the insulating layer and/or in the interface between the insulating layer and the semiconductor substrate, it is possible to prevent the peeling of the electrode which occurs in die bonding or wire bonding.

Other objects, features and advantages of the invention will become apparent from the following description of the embodiments of the invention taken in conjunction with the accompanying drawings.

### BRIEF DESCRIPTION OF DRAWINGS

FIG. 1 is a cross sectional view showing a structure of a semiconductor element which is a first embodiment of the present invention.

FIG. 2 is a characteristic chart showing peel strength to the film thickness of an amorphous silicon layer in the semiconductor element which is the first embodiment of the present invention.

FIG. 3 is a cross sectional view showing a structure of a semiconductor laser which is a second embodiment of the present invention.

101, 201—Semiconductor substrate,
102, 202—Multilayer crystal structure,
103, 203, 209, 210, 212—Insulating layer,
104, 106, 204, 208, 211—Amorphous silicon layer,
105, 107, 205, 207—Electrode

### DETAILED DESCRIPTION OF THE INVENTION

Hereinafter, embodiments of the present invention will be described in detail in accordance with the accompanying drawings. In addition, in all the drawings for describing the embodiments, the same numerals are given to the same elements in principle and the repeated description thereof is omitted.

### First Embodiment

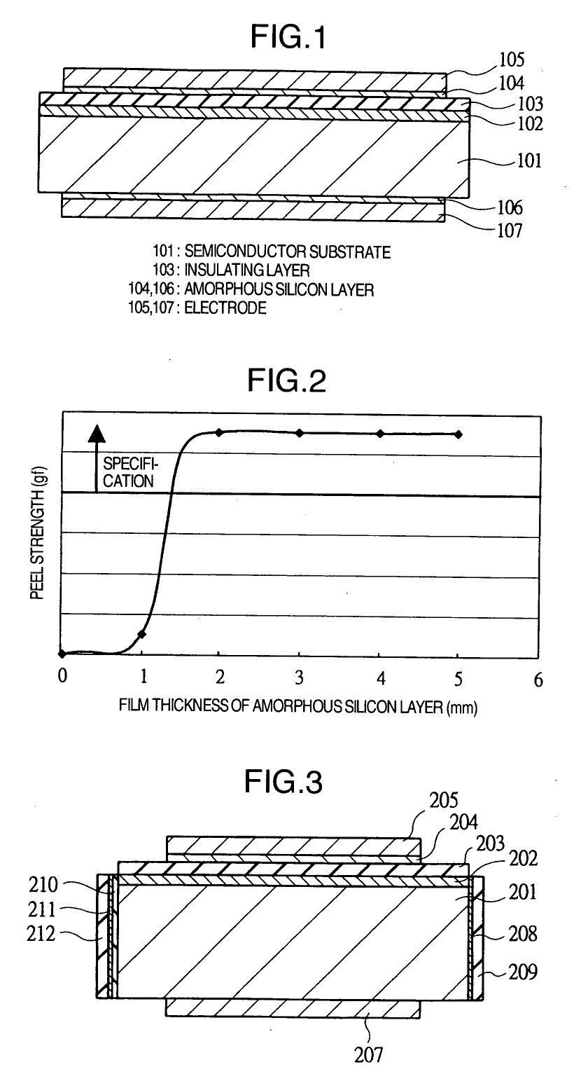

First, with reference to FIG. 1, an example of a structure of a semiconductor element which is a first embodiment of the present invention is described. FIG. 1 shows the structure of the semiconductor element.

The semiconductor element of this embodiment comprises: a semiconductor substrate 101; a multilayer crystal structure 102, an insulating layer 103, an amorphous silicon layer 104, and an electrode 105 which are formed on the surface of this semiconductor substrate 101; and an amorphous silicon layer 106 and an electrode 107 which are formed on the rear face of the semiconductor substrate 101, and the like.

In this semiconductor element, particularly, the amorphous silicon layers 104 and 106, to which hydrogen is not added, are made of an amorphous silicon in which many dangling bonds exist. The amorphous silicon layers 104 and 106, in which these many dangling bonds exist, can be obtained by adding no active gas, such as hydrogen, oxygen, and nitrogen, when forming the amorphous silicon layer.

Moreover, the film thickness of the amorphous silicon layers 104 and 106 is 2 nm or more, and the upper limit thereof is to the extent of not affecting the characteristic. The reason to restrict the film thickness of the amorphous silicon layers 104 and 106 to 2 nm or more this way is described with reference to FIG. 2. FIG. 2 shows the relation between the peel strength and the film thickness of the amorphous silicon layer.

If the thickness of the amorphous silicon layers 104 and 106 is less than 2 nm, the peel strength is low and a sufficient adhesion can not be obtained. This is because in the surface of the insulating layer 103 or in the surface of the semiconductor substrate 101, on which the amorphous silicon layers 104 and 106 are to be formed, there exist approximately 2 nm irregularities, and if the amorphous silicon layer is formed in the film thickness of 2 nm or less, then a region in which the amorphous silicon layer is non-uniform occurs in the interface between the insulating layer 103 and the electrode 105, or between the semiconductor substrate 101 and the electrode 107. In this case, it is impossible to satisfy the adhesion strength sufficiently and peeling will occur. So, in this embodiment, the film thickness of the amorphous silicon layers 104 and 106 is restricted to 2 nm or more.

Next, an example of a production process of the semiconductor element of this embodiment is described referring to FIG. 1.

In the production process of the semiconductor element of this embodiment, on the surface of the semiconductor substrate 101, which serves as an underlayer, the multilayer crystal structure 102 is formed first. After that, with the use of a thermal CVD method, photolithography, and etching, the insulating layer 103 made of Si or Al as the main material is formed on the surface of the multilayer crystal structure 102 for the purpose of decreasing the operating current. Then, on the surface of the insulating layer 103, the amorphous silicon layer 104 in which many dangling bonds exist is formed on the order of 3 nm in film thickness using an ECR sputtering method.

The reason to use this ECR sputtering method is that in order to suppress physical damages applied to the semiconductor substrate 101 and oxidization of the surface of the semiconductor substrate 101 due to high temperature when forming the amorphous silicon layer 104, a sputtering method which is a process in a vacuum containing extremely few impurities is used. Because an ECR sputtering method, in particular, is a low damaging type, it is possible to reduce the damages to a semiconductor laser during deposition by sputtering, and additionally, a precise insulating layer which is in a close to crystalline condition can be obtained.

After that, the electrode 105 in the surface side is formed by an electron beam evaporation method or the like. Accordingly, the formation of the surface side of the semiconductor substrate 101 is completed.

Subsequently, in the rear face side of the semiconductor substrate 101, first, on the rear face of the semiconductor substrate 101, like in the surface side, the amorphous silicon layer 104, in which many dangling bonds exist, is formed on the order of 3 nm in film thickness using an ECR sputtering method. Then, the electrode 107 in the rear face side is formed by an electron beam evaporation method or the like. Accordingly, the formation of the rear face side of the semiconductor substrate 101 is completed.

In this way, the semiconductor element is completed in which the multilayer crystal structure 102, the insulating layer 103, the amorphous silicon layer 104, and the electrode 105 are formed on the surface of the semiconductor substrate 101, and the amorphous silicon layer 106 and the electrode 107 are formed on the rear face of the semiconductor substrate 101.

According to the semiconductor element completed this way, as a result of inserting the amorphous silicon layers 104 and 106, in which many dangling bonds exist, in the interface between the electrode 107 and the semiconductor substrate 101 (in the rear face side), and in the interface between the electrode 105 and the insulating layer 103 (in the surface side), an incidence rate of the peeling of the electrode in die bonding or wire bonding reduced significantly from 30% in the past to 2%.

Note that, other than in the interface between the electrode 107 and the semiconductor substrate 101, and in the interface between the electrode 105 and the insulating layer 103, these amorphous silicon layers 104 and 106 can be inserted also in the interface between the insulating layer and the semiconductor substrate in the case where the insulating layer is formed in the surface of the semiconductor substrate, and in this case the same result was obtained also in the incidence rate of the peeling of the electrode in die bonding or wire bonding.

Accordingly, as in the semiconductor element of this embodiment, by inserting the amorphous silicon layers 104 and 106 in the interface between the electrode 107 and the semiconductor substrate 101, in the interface between the electrode 105 and the insulating layer 103, and in the interface between the insulating layer and the semiconductor substrate, the peeling of the electrode which occurs in die bonding or wire bonding can be prevented.

### Second Embodiment

Although in the first embodiment a semiconductor element taken as an example has been described, in this embodiment a semiconductor laser taken as an example will be described.

First, with reference to FIG. 3, an example of a structure of a semiconductor laser which is a second embodiment of the present invention is described. FIG. 3 shows a structure of the semiconductor laser.

The semiconductor laser of this embodiment comprises: a semiconductor substrate 201; a multilayer crystal structure 202, an insulating layer 203, an amorphous silicon layer 204, and an electrode 205 which are formed on the surface of this semiconductor substrate 201; an electrode 207 formed on the rear face of the semiconductor substrate 201; an amorphous silicon layer 208 and an insulating layer 209 formed in an oscillating surface of light of the semiconductor substrate 201; an insulating layer 210, an amorphous silicon layer 211, and an insulating layer 212 which are formed in a non-oscillating surface of light of the semiconductor substrate 201, and the like. The insulating layer 209 formed in the oscillating surface of light of this semiconductor substrate 201 serves as an optical reflective layer, and the insulating layer 210 and the insulating layer 212 which are formed in the non-oscillating surface serve as an optical multilayer reflective layer.

In this semiconductor laser, as in the first embodiment described above, the amorphous silicon layers 204, 208, and 211 are made of an amorphous silicon, to which hydrogen is not added and in which many dangling bonds exist, and this film thickness is 2 nm or more, and the upper limit thereof is to the extent of not affecting the characteristic. In addition, even if the amorphous silicon layers 208 and 211 in the film thickness of 2 nm are inserted in the oscillating surface and non-oscillating surface of light, respectively, a variation of the reflection factor is 0.01% or less, which is not a problem.

Next, an example of a production process of the semiconductor laser of this embodiment is described referring to FIG. 3.

In the production process of the semiconductor laser of this embodiment, first, in the surface side of the semiconductor substrate 201, like in the first embodiment, the multilayer crystal structure 202, the insulating layer 203, the amorphous silicon layer 204, and the electrode 205 are formed on the surface of the semiconductor substrate 201, in sequence. Then, in the rear face side of the semiconductor substrate 201, the electrode 207 in the rear face side is formed on the rear face of the semiconductor substrate 201. Thus, the formation of the surface side and the rear face side of the semiconductor substrate 201 is completed.

Subsequently, in the oscillating surface side of light of the semiconductor substrate 201, like in the first embodiment, for example, the amorphous silicon layer 208 is formed on the order of 3 nm in film thickness using an ECR sputtering method, and thereafter the insulating layer 209 is formed using a thermal CVD method, photolithography, and etching. Thus, the formation of the oscillating surface side of light in the semiconductor substrate 201 is completed.

Then, in the non-oscillating surface side of light of the semiconductor substrate 201, the insulating layer 210 is formed using a thermal CVD method, photolithography, and etching, and then, like in the oscillating surface side, for example, the amorphous silicon layer 211 is formed on the order of 3 nm in film thickness using an ECR sputtering method, and thereafter the insulating layer 212 is formed using a thermal CVD method, photolithography, and etching. Thus, the formation of the non-oscillating surface side of light of the semiconductor substrate 201 is completed.

In this way, the semiconductor laser is completed in which the multilayer crystal structure 202, the insulating layer 203, the amorphous silicon layer 204, and the electrode 205 are formed on the surface of the semiconductor substrate 201, the electrode 207 is formed on the rear face of the semiconductor substrate 201, the amorphous silicon layer 208 and the insulating layer 209 are formed in the oscillating surface of light of the semiconductor substrate 201, and the insulating layer 210, the amorphous silicon layer 211, and the insulating layer 212 are formed in the non-oscillating surface of light of the semiconductor substrate 201.

According to the semiconductor laser completed this way, as a result of inserting the amorphous silicon layers 208 and 211, in which many dangling bonds exist, in the interface between the insulating layer 209 and the semiconductor substrate 201 (in the oscillating surface side), and in the interface between the insulating layers 210 and 212 (in the non-oscillating surface side), the incidence rate of delamination of the reflective layers due to the semiconductor substrate 201 and the insulating layers 209, 210, and 212 was reduced from 20% in the past to 1% or less.

Accordingly, by inserting the amorphous silicon layer 204 in the interface between the electrode 205 and the insulating layer 203 as in the semiconductor laser of this embodiment, the same effect as that of the first embodiment is obtained, and by inserting the amorphous silicon layers 208 and 211 in the interface between the insulating layer 209, which serves as a reflective layer, and the semiconductor substrate 201, and in the interface between the insulating layers 210 and 212, which serve a multilayer reflective layer, lifting and delamination of the reflective layers can be prevented without affecting the variation of the reflection factor.

As described above, although the invention made by the present inventor has been described based on the embodiments, it is obvious that the present invention is not restricted to the above embodiments and various modifications can be made without departing from the scope thereof.

In semiconductor elements and semiconductor lasers like in the present invention, a further production cost reduction is requested, wherein the adhesion of electrode layers, insulating layers, and optical reflective layers formed in the surface of a semiconductor substrate is a critical problem for enabling improvement in the yield in the manufacturing process, as well as in a long-term stable operation. The present invention enables improvement in the yield in the manufacturing process as well as in reliability, and can be utilized as a basic technology essential for structures of semiconductor products in general such as semiconductor elements and semiconductor lasers in the future.

1. A semiconductor element having an electrode in a surface and/or in a rear face of a semiconductor substrate, the semiconductor element having a structure in which an amorphous silicon layer is inserted in between the electrode and the semiconductor substrate, wherein hydrogen is not added to the amorphous silicon layer.

2. The semiconductor element according to claim 1, wherein in the case where an insulating layer is formed underneath the electrode, the semiconductor element has a structure in which an amorphous silicon layer is inserted in the interface between the electrode and the insulating layer and/or in the interface between the insulating layer and the semiconductor substrate, wherein hydrogen is not added to the amorphous silicon layer.

3. The semiconductor element according to claim 1, wherein the film thickness of the amorphous silicon layer is 2 nm or more.

4. A production process of a semiconductor element having an electrode in a surface and/or in a rear face of a semiconductor substrate, the process comprising forming in the surface and/or in the rear face of the semiconductor substrate an amorphous silicon layer, to which hydrogen is not added, and forming an electrode in the surface of the amorphous silicon layer.

5. The production process of a semiconductor element according to claim 4, wherein in the case where an insulating layer is formed underneath the electrode, the process further comprises forming an amorphous silicon layer in the interface between the electrode and the insulating layer and/or in the interface between the insulating layer and the semiconductor substrate, wherein hydrogen is not added to the amorphous silicon layer.

6. The production process of a semiconductor element according to claim 4, wherein the amorphous silicon layer is formed by an ECR sputtering method.

7. A semiconductor laser having a reflective layer in an oscillating surface of light of a semiconductor substrate and having a multilayer reflective layer in a non-oscillating surface of light of the semiconductor substrate, wherein the semiconductor laser has a structure in which an amorphous silicon layer is inserted in the interface between the reflective layer and the semiconductor substrate and/or in the interface between reflective layers of the multilayer reflective layer, wherein hydrogen is not added to the amorphous silicon layer.

8. The semiconductor laser according to claim 7, wherein the film thickness of the amorphous silicon layer is 2 nm or more.

9. A production process of a semiconductor laser having a reflective layer in an oscillating surface of light of a semiconductor substrate and having a multilayer reflective layer in a non-oscillating surface of light of the semiconductor substrate, wherein the process comprises forming an amorphous silicon layer in the interface between the reflective layer and the semiconductor substrate and/or in the interface between reflective layers of the multilayer reflective layer, wherein hydrogen is not added to the amorphous silicon layer.

10. The production process of a semiconductor laser according to claim 9, wherein the amorphous silicon layer is formed by an ECR sputtering method.
